(19) United States
(12) Patent Application Publication
(10) Pub. No.: US 2010/0315112 A1
(43) Pub. Date: Dec. 16, 2010

(54) SOCKET ADAPTER FOR TESTING SINGULATED ICS WITH WAFER LEVEL PROBE CARD

(75) Inventors: Hung Quoc Nguyen, Carrollton, TX (US); Damian Peter Lewis, Wylie, TX (US); Perry Fitzgerald Daniels, Frisco, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/775,126

(22) Filed: May 6, 2010

Related U.S. Application Data
(60) Provisional application No. 61/185,083, filed on Jun. 8, 2009.

(51) Int. Cl. G01R 31/02; G01R 1/06

(52) U.S. Cl. 324/756.02; 324/756.03

(57) ABSTRACT

An integrated probe card and socket adapter includes probe needles for probing a wafer including a plurality of CSP IC each having a plurality of bumps. A socket adapter includes a socket body having an elevated portion and a recessed base portion. The recessed base portion has a base portion thickness and includes a plurality of base portion through-holes that align with and receive the bumps on at least one of said plurality of CSP IC after singulation (singulated CSP IC) for securing the singulated CSP IC thereto. The elevated portion includes a plurality of elevated portion through-holes for fastening to the probe card when the probe card is underlying. The base portion thickness is sized so that the probe needles extend into the base portion through-holes a sufficient distance to contact the bumps of the singulated CSP IC for testing using the probe card.

### CROSS REFERENCE TO RELATED APPLICATIONS

This application claims the benefit of Provisional Application Ser. No. 61/185,083 entitled “Vertical Probe Card Socket Adapter”, filed Jun. 8, 2009, which is herein incorporated by reference in its entirety.

### FIELD

Disclosed embodiments relate testing of integrated circuits (ICs), and more particularly to test hardware for wafer level and package level IC testing.

### BACKGROUND

The manufacture of integrated circuits (ICs) involves testing the ICs to ensure that the ICs meet the manufacturer's and/or the customer's specifications. The testing of the ICs can generally takes place after fabrication in wafer form (i.e. “multiprobe”) and again after the ICs have been singulated and packaged. The testing of ICs in wafer form generally involves the use of probe pins housed in a probe card for making electrical contact with input/output pads of the IC. A conventional probe card is a cantilever probe card, having a plurality of cantilever probe pins.

Probe cards can result in difficulty in testing since the targets of the probe pins, the input/output pads of the ICs, can be extremely small and may be quite delicate. It is possible for a misaligned probe pin to miss an input/output pad, pierce an input/output pad in its entirety and damage underlying circuitry, fail to make electrical contact with an input/output pad, and so forth. Therefore, it can be difficult performing IC testing on a wafer. Not only is performing the test difficult, it can be even more difficult to debug the testing hardware and software, since there is a large degree of uncertainty involved using probe pins. Due to uncertainties, such as those described above, it can be difficult to determine what exactly is faulty: the test program, the test equipment, the probe card, the IC, and so forth.

A known engineering technique for debugging test hardware and software for use in testing ICs s makes use of an adapter board (also referred to as a “spider card”) to facilitate engineering “hand testing” of packaged ICs. The spider card can replace the probe card and can hold one or more packaged ICs. The use of packaged ICs can help eliminate many of the uncertainties involved in the use of probe pins, such as misaligned pins, spotty electrical contacts, and so forth. This technique can make use of packaged ICs that are known to be good in the test. For example, if the test still fails with the use of the spider card and the known good packaged ICs, then it is known that a fault lies within the test equipment. If the test passes, then it is known that a fault lies within the probe card.

One disadvantage of this known technique is that the use of a probe card and a spider card requires two separate card designs. This incurs additional designing and debugging time and cost. Furthermore, in most cases, the production run for a probe card and a spider card will tend to be small. Therefore, the production of the probe cards and the spider cards can be expensive.

A second disadvantage of this known technique is that in many instances, the design (e.g., electrical traces and parasitics) of the probe card will be different from the design of the spider card. Therefore, there the probe card and the spider card will generally behave electrically differently. This can lead to data correlation problems that can result in additional time and money spent in debugging and design.

Chip scale packaging (CSP) eliminates conventional packaging steps such as die bonding, wire bonding, and die level flip chip attach processes. In a typical CSP production flow, a wafer after completion of wafer fab processing is multiprobed, bumped, bump-probed (which is the final electrical test of the “CSP package”), singulated and then shipped to the customer. As noted above, there is often an engineering need to make electrical measurements on singulated ICs, such as for debugging test programs. In the case of CSP, since there is no production electrically testing after singulation in a CSP assembly flow, the need for data correlation between tested singulated CSP ICs and the wafer level is heightened as compared to conventional ICs. However, if a spider card is used to test the singulated CSP ICs and a probe card is used for the wafer level measurements of the CSP ICs, the probe card and the spider card will generally behave electrically differently due primarily to different probes, electrical traces on their respective PCB boards and related parasitics which can lead to data correlation problems that may result in additional time and money spent in debugging and design.

### SUMMARY

Disclosed embodiments solve the data correlation problem between wafer level bump probe of CSP wafers including CSP IC and testing the bumped CSP ICs after singulation which the Inventors have recognized such problems result because the wafer level probe uses a probe card while singulated chip test uses a bench setup (e.g., spider card). As used herein, bumps include any externally contactable metallization pattern that includes a plurality of protruding contact pads or pins including land grid arrays, pin grid arrays, where the length of the protrusion is at least 2 mils, and ICs having such bumps are referred to herein as CSP ICs.

Disclosed embodiments describe socket adapters for testing singulated CSP IC, that allow the final-production-test board used for wafer level bump probe to also be used for testing (e.g., engineering hand-test) singulated CSP IC. Disclosed socket adapters allow the probe card to be used with the socket adapter to test singulated CSP IC that thus renders spider cards unnecessary which saves cost and engineering time.

Since disclosed socket adapters enable the production probe card's production probe needles and signal traces to be used for testing singulated CSP IC, such as for characterization, measurement error introduced by known solutions involving separate probe cards for wafer level production test and spider cards for engineering/hand-test of singulated CSP IC is eliminated or at least significantly reduced.

In one disclosed embodiment a socket adapter for testing singulated CSP ICs comprises a socket body including an elevated portion and a recessed base portion. The recessed base portion has a base portion thickness and includes a plurality of base portion through-holes that align with and receive bumps on at least one singulated CSP IC for securing the singulated CSP IC thereto. The elevated portion includes a plurality of elevated portion through-holes for fastening to an underlying probe card. The base portion thickness is sized so that the probe needles extend into the base portion through-holes a sufficient distance to contact the bumps of the singulated CSP IC for testing the singulated CSP IC using the probe card.

### BRIEF DESCRIPTION OF THE DRAWINGS

FIG. 1A is a depiction of a vertical probe card that can be used with disclosed embodiments.

FIG. 1B is a depiction of a socket adapter according to a disclosed embodiment.

FIG. 1C is a depiction of a socket lid according to a disclosed embodiment.

FIG. 2A is a depiction of an integrated system comprising a vertical probe card with socket adapter thereon and a lid for the socket adapter, with the lid closed, according to a disclosed embodiment.

FIG. 2B is a depiction the integrated system shown in FIG. 2A comprising a vertical probe card with a socket adapter thereon and lid for the socket adapter, with the lid opened.

FIG. 3 depicts a cross sectional view of a singulated CSP IC including bumps/balls mounted on a socket adapter.

### DETAILED DESCRIPTION

Disclosed embodiments in this Disclosure are described with reference to the attached figures, wherein like reference numerals are used throughout the figures to designate similar or equivalent elements. The figures are not drawn to scale and they are provided merely to illustrate the disclosed embodiments. Several aspects are described below with reference to example applications for illustration. It should be understood that numerous specific details, relationships, and methods are set forth to provide a full understanding of the disclosed embodiments. One having ordinary skill in the relevant art, however, will readily recognize that the subject matter disclosed herein can be practiced without one or more of the specific details or with other methods. In other instances, well-known structures or operations are not shown in detail to avoid obscuring structures or operations that are not well-known. This Disclosure is not limited by the illustrated ordering of acts or events, as some acts may occur in different orders and/or concurrently with other acts or events. Furthermore, not all illustrated acts or events are required to implement a methodology in accordance with this Disclosure.

Notwithstanding that the numerical ranges and parameters setting forth the broad scope of this Disclosure are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

One disclosed embodiment comprises a socket adapter for testing singulated CSP ICs that comprises a socket body including an elevated portion and a recessed base portion. The recessed base portion has a base portion thickness and includes a plurality of base portion through-holes that align with and receive bumps on singulated CSP IC for securing the singulated CSP IC thereto. The elevated portion includes a plurality of elevated portion through-holes for fastening to an underlying vertical probe card having vertical probe needles. The base portion thickness is sized so that the probe needles extend into the base portion through-holes a sufficient distance to contact the bumps of the singulated CSP IC for testing the singulated CSP IC using the probe card. Significantly, the probe card can be the same probe card used in production for the wafer level, such as the production probe card for final bump probe.

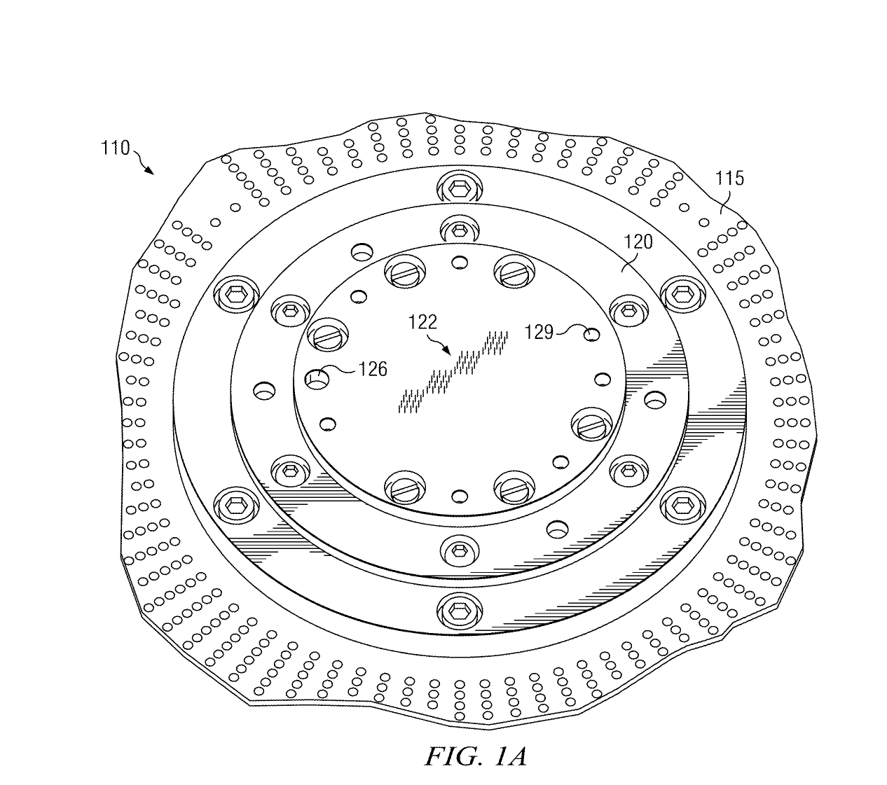

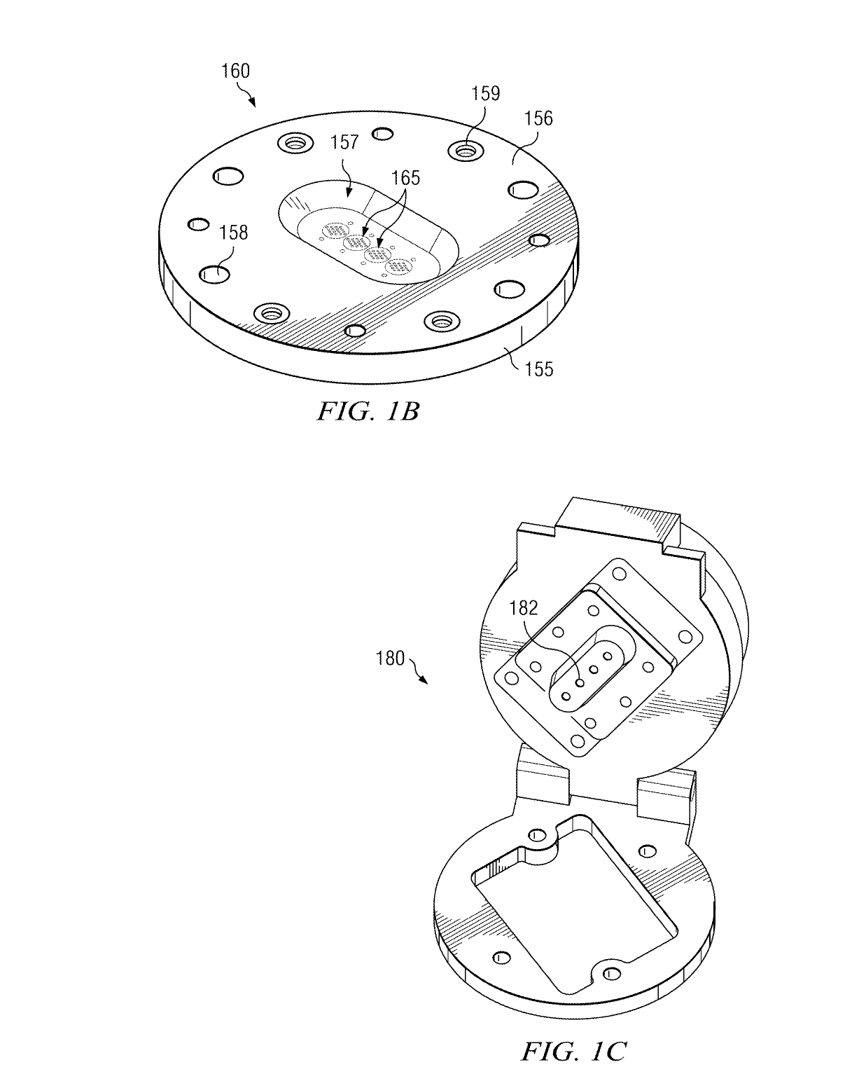

FIG. 1A is a depiction of a vertical probe card 110 that can be used with disclosed embodiments. Probe card 110 includes a PCB board 115, and a probe head 120 secured to the PCB board 115. Vertical probe needles 122 are in an exemplary arrangement that can be seen to be clustered in four (4) groups of 16 (4×4), which are positioned to match the bump pattern of bumps/balls for a CSP IC. As described herein, these same vertical probe needles 122 are used for final bump probe for probing in wafer form, and for testing the same CSP IC in die form once singulated enabled by the addition of a socket adapter (not shown) on the probe card 110 as described in more detail below. Probe card 110 also has socket screw (or other fastener) holes 129 for mounting a socket adapter thereon. In addition, probe card 110 has socket guide-pin holes 126. The probe needles 122 generally comprise compressible probe needles that allow a degree of compression. The compression resistance of the probes generally depends on the probe length and thickness, so there is ratio of thickness to length that can be generally maintained. In operation, vertical probe needles 122 provide a slight scrub capable of removing oxide buildup on the bumps/balls when present, but not as noticeable as the scrub generated by use of conventional cantilever probe needles.

FIG. 1B is a depiction of a socket adapter 160 according to a disclosed embodiment. The socket adapter 160 includes a socket body 155 including an elevated portion 156 and a recessed base portion 157. The thickness of the recessed base portion 157 is sized so that the vertical probe needles 122 extend into the base portion probe needle through-holes 165 a sufficient distance to contact the bumps/balls of the singulated CSP IC for testing the singulated CSP IC using the probe card 110. The probe needle through-holes 165 are seen in recessed based portion 157 to match the positions of probe needles 122 which as described above are shown in an exemplary arrangement comprising four (4) groups of 16 in FIG. 1A. The elevated portion 156 includes a plurality of elevated portion through-holes 158 for fastening to an underlying probe card, such as probe card 110. Socket adapter 160 also includes a plurality of lid screw holes 159 for mounting a lid (not shown in FIG. 1B) thereon.

FIG. 1C is a depiction of a socket lid 180 according to a disclosed embodiment. Lid 180 is seen to include a plurality (four (4)) air flow vents 182 that permits flowing heated or chilled gas (e.g. air or nitrogen) for testing four (4) singulated CSP IC over high (e.g. 85 or 125° C.) or low temperatures (−40 or −55° C.).

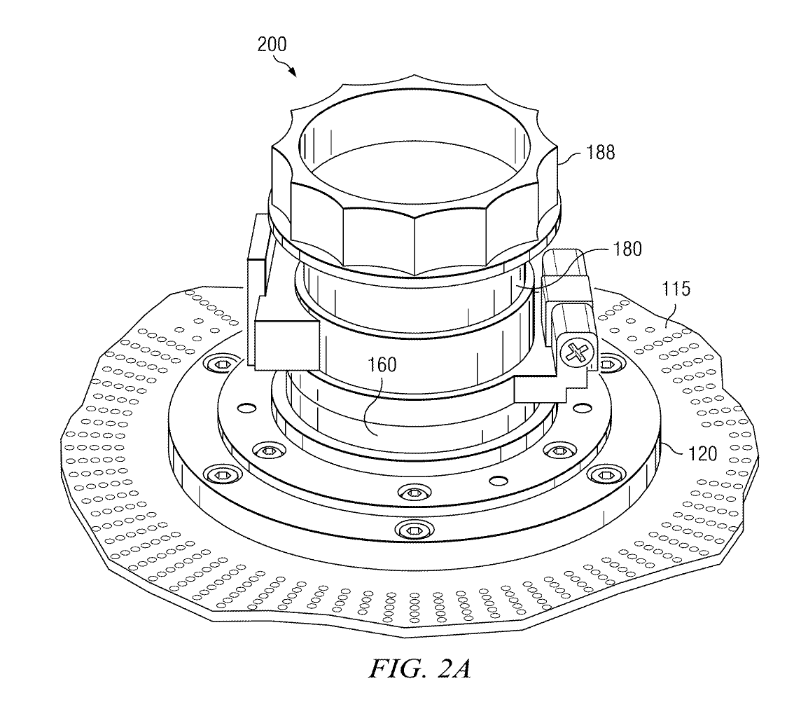

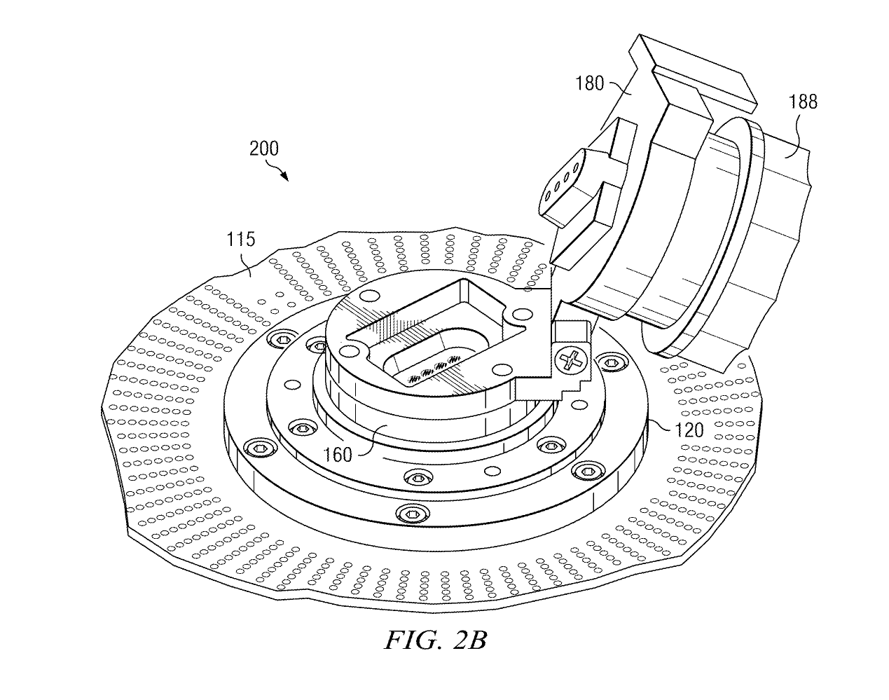

FIG. 2A is a depiction of an integrated system 200 comprising a probe card 110 with a socket adapter 160 thereon and a lid 180 for the socket adapter, with the lid closed, according to a disclosed embodiment. The lid 180 is seen to include structure for manual contact pressure control and lock 188. In one embodiment a threaded ring which can be adjusted manually is used to set the contact pressure for device testing. FIG. 2B is a depiction the integrated system 200 comprising a probe card 110 with socket adapter 160 thereon and lid 180 for the socket adapter shown in FIG. 2A, with the lid 180 opened.

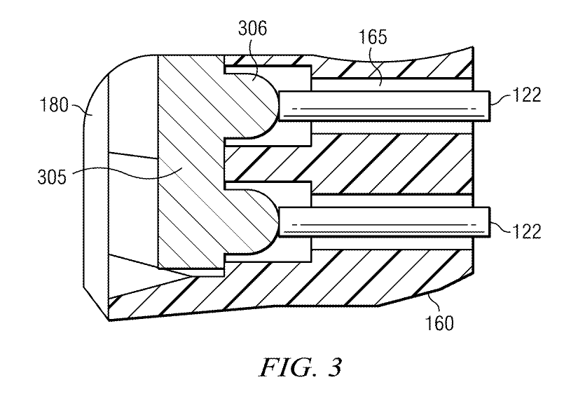

FIG. 3 depicts a cross sectional view of a singulated CSP IC 305 including bumps/balls 306 mounted on a socket adapter 160. Bumps 306 of the singulated CSP IC 305 are within probe needle through-holes 165 being contacted by probe needles 122 of a probe card (not shown), according to a disclosed embodiment. An exemplary height for the bumps/balls 306 can be about 10 mils, and an exemplary diameter of 12 mils (1 mm=mils*2.54/100). With an exemplary probe needle through-hole 165 depth of 46 mils, and a probe needle 122 length of 41 mils, the compression of the probe needles 122 is about 5 mils which allows for variations including bump/ball height, probe needle height, and non-planarities.

Advantages of disclosed embodiments include elimination of a spider card and its associated design for testing singulated CSP IC. Disclosed embodiments enables development using a probe card without a probe system, as well as temperature and gauge reproducibility and repeatability (GR&R characterization) with a production probe card. In addition, disclosed embodiments facilitate accurate guard-banding and prediction of test solution performance in production, enable early detection and prevention of potential production issues, and enhances debugging.

Regarding lead time and cost, disclosed embodiments provide shorter lead-times than a cantilever probe card and spider card combined, and comparable cost to cantilever probe card and spider card combined.

Disclosed embodiments may be extended to non-bumped die which as described are defined herein as any externally contactable metallization pattern that includes a plurality of protruding contact pads or pins, such as land grid arrays and pin grid arrays, where the length of the protrusion is at least 2 mils. One exemplary way of securing and aligning non-bumped singulated die is realized by having the recessed portion 157 of the adapter socket base further comprise one or more cavities (one cavity for each singulated die) that have a cavity dimension sized to be slightly more than the area dimensions (e.g., length and width for a rectangular die) of the singulated die, so that upon die insertion into the cavity aligns the die pads or pins to the probe needles 122. In one specific embodiment, the height of the probe needle through-holes 165 can be shortened to allow compressible probe needles to protrude a distance of about 2 to 4 mils out from the probe needle holes 165 in order to make reliable contact with the die pads or pins.

While various disclosed embodiments have been described above, it should be understood that they have been presented by way of example only, and not limitation. Numerous changes to the subject matter disclosed herein can be made in accordance with this Disclosure without departing from the spirit or scope of this Disclosure. In addition, while a particular feature may have been disclosed with respect to only one of several implementations, such feature may be combined with one or more other features of the other implementations as may be desired and advantageous for any given or particular application.

Thus, the breadth and scope of the subject matter provided in this Disclosure should not be limited by any of the above explicitly described embodiments. Rather, the scope of this Disclosure should be defined in accordance with the following claims and their equivalents.

The terminology used herein is for the purpose of describing particular embodiments only and is not intended to be limiting. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which embodiments of the invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

We claim:

1. A socket adapter for testing singulated chip scale package (CSP) integrated circuits (ICs), comprising:
a socket body including an elevated portion and a recessed base portion, said recessed base portion having a base portion thickness and including a plurality of base portion through-holes that align with and receive bumps on at least one singulated CSP IC for securing said singulated CSP IC thereto;
wherein said elevated portion includes a plurality of elevated portion through-holes for fastening to an underlying probe card including a plurality of probe needles, and
wherein said base portion thickness is sized so that said probe needles extend into said base portion through-holes a sufficient distance to contact said bumps of said singulated CSP IC for testing said singulated CSP IC using said probe card.

2. The socket adapter of claim 1, further comprising a lid for closing a volume over said recessed base portion, wherein said lid includes at least one vent hole for temperature testing.

3. The socket adapter of claim 2, wherein said lid further comprises a structure for manual contact pressure control.

4. The socket adapter of claim 1, wherein said at least one singulated CSP IC comprises a plurality of CSP IC.

5. An integrated probe card and socket adapter for chip scale package (CSP) integrated circuits (ICs), comprising:
a probe card comprising a printed circuit board (PCB) having a plurality of probe needles secured and coupled to said PCB for probing a wafer including a plurality of CSP IC each having a plurality of bumps, and
a socket adapter, comprising:
a socket body including an elevated portion and a recessed base portion, said recessed base portion having a base portion thickness and including a plurality of base portion through-holes that align with and receive said plurality of bumps on at least one of said plurality of CSP IC after singulation (singulated CSP IC) for securing said singulated CSP IC thereto;
wherein said elevated portion includes a plurality of elevated portion through-holes for fastening to said probe card when said probe card is underlying, and
wherein said base portion thickness is sized so that said probe needles extend into said base portion through-holes a sufficient distance to contact said bumps of said singulated CSP IC for testing said singulated CSP IC using said probe card.

6. The integrated probe card and socket adapter of claim 5, wherein said probe needles comprise compressible probe needles.

7. The integrated probe card and socket adapter of claim 6, wherein a length of said compressible probe needles is at least 2 mils<a depth of said plurality of base portion through-holes.

8. The integrated probe card and socket adapter of claim 5, wherein said socket adapter further comprises a lid for closing a volume over said recessed base portion, wherein said lid includes at least one vent hole for temperature testing.

9. The integrated probe card and socket adapter of claim 10, wherein said lid further comprises a structure for manual contact pressure control.

10. The integrated probe card and socket adapter of claim 5, wherein said at least one singulated CSP IC comprises a plurality of CSP IC.

11. A method of testing singulated chip scale package (CSP) integrated circuits (ICs), comprising:
placing at least one singulated CSP IC having a frontside surface including a plurality of bumps coupled to bond pads into a socket adapter, wherein said socket adapter includes through-holes that align with and receive said bumps for securing said singulated CSP IC thereto, and
testing said CSP IC using a probe card comprising a plurality of probe needles, wherein said plurality of probe needles contact said plurality of bumps.

12. The method of claim 11, wherein said socket adapter is mounted on said probe card before said placing of said singulated CSP IC.

13. The method of claim 11, wherein said probe card is a production probe card used for bump probe of wafers having a plurality of ICs that have a bump pattern that matches a bump pattern on said singulated CSP IC.

14. The method of claim 13, further comprising:
bump probing at least one die on said wafers having a plurality of ICs that have a bump pattern that matches a bump pattern on said singulated CSP IC testing, and
correlating data between said bump probing and said testing.

15. The method of claim 11, wherein data acquired from said testing is used to verify a performance of said probe card.

16. The method of claim 11, wherein said testing is used to develop a probe solution with said probe card exclusive of a probe system.

17. The method of claim 13, wherein said socket adapter further comprises a lid for closing a volume over said recessed base portion, wherein said lid includes at least one vent hole, and wherein said testing comprises flowing a gas into said vent hole for temperature testing.
